(19) United States
(12) Patent Application Publication
(10) Pub. No.: US 2026/0367932 A1
(43) Pub. Date: Nov. 19, 2026

(54) LINK LIBRARY UNIVERSAL SYSTEM, AND CONTROLLING METHOD AND APPARATUS FOR LINK LIBRARY UNIVERSAL SYSTEM

(71) Applicant: ELECTRIC POWER RESEARCH INSTITUTE, CHINA SOUTHERN POWER GRID, Guangzhou, Guangdong (CN)

(72) Inventors: Binjiang HU, Guangzhou, Guangdong (CN); Yihua ZHU, Guangzhou, Guangdong (CN); Libin HUANG, Guangzhou, Guangdong (CN); Haiping GUO, Guangzhou, Guangdong (CN); Liang TU, Guangzhou, Guangdong (CN); Chao LUO, Guangzhou, Guangdong (CN); Jiawei YU, Guangzhou, Guangdong (CN); Chengxiang LI, Guangzhou, Guangdong (CN); Dongxu CHANG, Guangzhou, Guangdong (CN); Mingkang WU, Guangzhou, Guangdong (CN)

(73) Assignee: ELECTRIC POWER RESEARCH INSTITUTE, CHINA SOUTHERN POWER GRID, Guangzhou, Guangdong (CN)

(21) Appl. No.: 19/476,001

(22) PCT Filed: Apr. 25, 2024
(86) PCT No.: PCT/CN2024/089712

§ 371 Date: Oct. 16, 2025

(30) Foreign Application Priority Data
May 31, 2023 (CN) 202310645213.9

(51) Int. Cl. G06F 9/445; G06F 8/41; G06F 9/455

(52) U.S. Cl. CPC G06F 9/44521; G06F 8/41; G06F 9/455

(57) ABSTRACT

A link library universal system, and a control method and apparatus for the link library universal system. The system comprises: a work station (10), used to store multiple link libraries (11), wherein each link library (11) is a set of library files used in a link process; multiple simulators (12), used to realize hardware simulation; and a universal apparatus (13), in communication connection with the work station (10) and the multiple simulators (12), wherein the universal apparatus (13) is used for calling any link library (11) and sending the called link library (11) to any simulator (12). The multiple link libraries (11) are combined, and the multiple simulators (12) are also combined; any link library (11) is called by means of using the universal apparatus (13), and each called link library (11) is sent to any simulator (12).

This application claims the priority of Chinese Patent Application No. 202310645213.9, titled “LINK LIBRARY UNIVERSAL SYSTEM, AND CONTROLLING METHOD AND APPARATUS FOR LINK LIBRARY UNIVERSAL SYSTEM”, filed on May 31, 2023 with the China National Intellectual Property Administration, which is incorporated herein by reference in its entirety.

### FIELD

The present disclosure relates to the technical field of link libraries, and in particular to a universal system for link libraries, and a method and an apparatus for controlling the universal system for the link libraries.

### BACKGROUND

The renewable energy sector now boasts a diverse range of manufacturers and product series. The accuracy of real-time simulation for renewable energy devices depends on digital simulation models provided by manufacturers. Currently, there are plenty of mainstream real-time simulators available, such as Real Time Digital Simulation (RTDS) system, Real Time Laboratory (RTLAB, a real-time digital system simulation test platform), HyperSim (a real-time digital power system simulation system), and Advanced Digital Power System Simulator (ADPSS, an all-digital real-time simulation apparatus). The conventional solution employs a mainstream real-time simulator to simulate grid-connected renewable-energy device. The renewable energy manufacturers develop digitally encapsulated models (link libraries) designed for specific real-time simulators to simulate renewable-energy controllers in real time.

However, in the conventional solutions, configuration between link libraries and simulation platforms (or referred to as simulators) is only in a one-to-one manner, restricting a user to perform simulation by using only one simulation platform, thereby resulting in poor user experience.

### SUMMARY

The present disclosure aims to provide a universal system for link libraries, and a method and an apparatus for controlling the universal system for the link libraries, so as to address the issue that, in the conventional technology, configuration between link libraries and simulation platforms is only in a one-to-one manner, restricting a user to perform simulation by using only one simulation platform, thereby resulting in poor user experience.

To achieve the above objective, in a first aspect, a universal system for link libraries is provided in the present disclosure. The universal system includes: a workstation, configured to store multiple link libraries, where each of the multiple link libraries is a collection of library files to be used in a linking process; multiple simulators, configured to simulate hardware; and a universal apparatus, where the universal apparatus is communicatively connected to the workstation and the multiple simulators, and is configured to invoke any one of the multiple link libraries and send the invoked link library to any one of the multiple simulators.

In an embodiment, the universal apparatus includes: a network interface, where the universal apparatus is communicatively connected to the workstation through the network interface, and is configured to receive the invoked link library from the workstation through the network interface; and an optical fiber interface, where the universal apparatus is communicatively connected to the multiple simulators through the optical fiber interface.

In an embodiment, the multiple link libraries include an RTLAB link library, an ADPSS link library, and a HyperSim link library, and the multiple simulators include an RTDS simulator, an RTLAB simulator, an ADPSS simulator, and a HyperSim simulator.

In an embodiment, the universal apparatus further includes: an RTLinux operating system, configured to provide a set of supporting functions for a hardware real-time process and control a simulation process; and a GCC compiler, configured to perform code compilation in conjunction with the RTLinux operating system.

In a second aspect of the present disclosure, a method for controlling the universal system for link libraries is provided in the present disclosure. The method includes:
obtaining first interface information of multiple first invocation interfaces, where the multiple first invocation interfaces correspond to the multiple link libraries in a one-to-one manner, and are configured to invoke the corresponding link libraries;
   obtaining second interface information of a second invocation interface, where the second invocation interface is configured to invoke a first invocation interface of the multiple first invocation interface s; and
invoking, through the second invocation interface, a first invocation interface of the multiple first invocation interfaces according to the second interface information, to cause the invoked first invocation interface to invoke a link library of the multiple link libraries which corresponds to the first invocation interface according to the first interface information.

In an embodiment, after the obtaining second interface information of a second invocation interface, the method further includes:
obtaining a task scheduling list, where the task scheduling list includes multiple tasks, each of the multiple tasks includes a pre-invoked link library of the multiple link libraries; and
traversing the task scheduling list and executing the multiple tasks in order.

In an embodiment, the executing the multiple tasks in order includes:
obtaining priorities of the multiple tasks, and executing the multiple tasks in a descending order of priority; and
obtaining an association relationship among the multiple tasks, and executing the multiple tasks in order according to the association relationship, where the association relationship includes a serial relationship and a parallel relationship, the serial relationship indicates that the multiple tasks are sequentially executed, and the parallel relationship indicates that the multiple tasks are executed in parallel.

In an embodiment, after the invoking, through the second invocation interface, a first invocation interface of the multiple first invocation interfaces according to the second interface information, to cause the invoked first invocation interface to invoke a link library of the multiple link libraries which corresponds to the first invocation interface according to the first interface information, the method further includes:
controlling a simulator receiving the invoked link library to perform simulation; and
determining that the simulator is abnormal in a case that no response is received from the simulator within a predetermined duration.

In an embodiment, after the invoking, through the second invocation interface, a first invocation interface of the multiple first invocation interfaces according to the second interface information, to cause the invoked first invocation interface to invoke a link library of the multiple link libraries which corresponds to the first invocation interface according to the first interface information, the method further includes:
terminating the invocation of the link library upon receiving a termination command, where the termination command is generated by the workstation.

In a third aspect of the present disclosure, an apparatus for controlling the universal system for link libraries is provided in the present disclosure. The apparatus includes: a first obtaining unit, configured to obtain first interface information of multiple first invocation interfaces, where the multiple first invocation interfaces correspond to the multiple link libraries in a one-to-one manner, and are configured to invoke the corresponding link libraries; a second obtaining unit, configured to obtain second interface information of a second invocation interface, where the second invocation interface is configured to invoke a first invocation interface of the multiple first invocation interfaces; and a first processing unit, configured to invoke, through the second invocation interface, a first invocation interface of the multiple first invocation interfaces according to the second interface information, to cause the invoked first invocation interface to invoke a link library of the multiple link libraries which corresponds to the first invocation interface according to the first interface information.

With the technical solution in the present disclosure, multiple link libraries are combined and multiple simulators are combined. The universal apparatus invokes any one of the link libraries and sends the invoked link library to any one of the simulators, enabling many-to-many configuration between the link libraries and simulation platforms, that is, the link libraries are shared among the simulators. In this way, a user can perform simulation by using different platforms and different link libraries, thereby improving user experience.

### BRIEF DESCRIPTION OF THE DRAWINGS

The drawings constituting a part of the present disclosure are used to provide a further understanding of the present disclosure, and the exemplary embodiments and descriptions of the present disclosure are used to explain the present disclosure, and do not constitute an improper limitation to the present disclosure. Among the accompanying drawings:

FIG. 1 is a schematic structural diagram of a universal system for link libraries according to an embodiment of the present disclosure;

FIG. 2 is a structural block diagram of hardware of a mobile terminal for implementing a method for controlling a universal system for link libraries according to an embodiment of the present disclosure;

FIG. 3 is a flowchart of a method for controlling a universal system for link libraries according to an embodiment of the present disclosure;

FIG. 4 is a schematic diagram of software logic of a universal system for link libraries according to an embodiment of the present disclosure; and

FIG. 5 is a structural block diagram of an apparatus for controlling a universal system for link libraries according to an embodiment of the present disclosure.

### REFERENCE NUMERALS ARE LISTED AS FOLLOWS

| | | | |
|---|---|---|---|
| 102 | Processor | 104 | Memory |
| 106 | Transmission device | 108 | Input/Output device |
| 10 | Workstation | 11 | Link library |
| 12 | Simulator | 13 | Universal apparatus |
| 14 | Network interface | 15 | Optical fiber interface |
| 16 | RTLinux operating system | 17 | GCC compiler |
| 18 | Hardware | | |

### DETAILED DESCRIPTION

It should be noted that the embodiments of the present disclosure and features in the embodiments can be combined with each other without conflict. The present disclosure is described in detail below in conjunction with the embodiments and with reference to the drawings.

To enable those skilled in the art to understand the solutions of the present disclosure, the technical solutions of the embodiments of the present disclosure are described clearly and completely below in conjunction with the drawings of the embodiments of the present disclosure. Apparently, the embodiments described below are only some of the embodiments of the present disclosure, rather than all of the embodiments of the present disclosure. Any other embodiments obtained by those skilled in the art based on the embodiments in the present disclosure without creative efforts shall fall within the protection scope of the present disclosure.

It should be noted that the terms “first”, “second” and the like in the specification, the claims and the drawings of the present disclosure are used to distinguish similar objects rather than to describe a particular sequence or order. It should be understood that the terms used in such a way are interchangeable in proper circumstances to describe the embodiments of the present disclosure. Moreover, the terms “include,” “comprise”, and any other variants thereof are intended to be non-exclusive. For example, a process, method, system, product, or device that includes a series of steps or units is unnecessarily limited to those expressly listed steps or units, but may include other steps or units not expressly listed or inherent in such process, method, product, or device.

For convenience of description, some concepts and terms involved in the embodiments of the present disclosure embodiments are described below.

Renewable energy technology, such as nuclear energy technology, solar energy technology, coal-fired power technology, magnetohydrodynamic power generation technology, geothermal energy technology, and ocean energy technology, is a pillar of high technology. The nuclear energy technology and solar energy technology are the primary hallmarks of renewable energy technology. The development and utilization of nuclear and solar energy have broken away from the traditional energy paradigm dominated by petroleum and coal, ushering in a new era of energy. Currently, wind and solar energy are the mainstream, and apparatuses that control the wind and solar energy are referred to as controllers.

A photovoltaic controller is an automatic control device used in a solar power generation system to control multiple solar cell arrays to charge batteries and control the batteries to supply power to a load of a solar inverter. The photovoltaic controller adopts a high-speed CPU microprocessor and a high-precision analog-to-digital (A/D) converter, functioning as a microcomputer-based data acquisition and monitoring control system. The photovoltaic controller can rapidly acquire an operating status of a photovoltaic system in real-time, immediately access to operational data of a PV station, as well as accumulating detailed historical data of the PV station, thereby providing an accurate and sufficient basis for evaluating the rationality of the PV system design and verifying the reliability of system component quality. In addition, the photovoltaic controller is provided with a serial communication data transmission function, enabling centralized management and remote control over multiple photovoltaic system substations.

A wind turbine controller regulates and controls electrical energy generated by a wind turbine. The wind turbine controller sends regulated energy to a direct-current load or an alternating-current load and directs surplus energy to charge a battery pack according to the characteristic curve of batteries. If generated energy fails to meet the needs of the load, the wind turbine controller controls the batteries to supply electrical energy to the load. The wind turbine controller prevents the batteries from being overcharged after the batteries are fully charged. When energy stored in the batteries is depleted, the wind turbine controller prevents over-discharge to protect the batteries.

The wind turbine controller controls the wind turbine to intelligently charge the batteries through a pulse width modulation (PWM) stepless unloading method. If the electrical energy generated by the wind turbine exceeds the capacity of the batteries, the control system dissipates the surplus energy. In a common control method, all unloading devices are connected, the batteries are not fully charged, and the energy is consumed by the unloading devices, leading to a waste of energy. In another common control method, unloading devices are connected at different stages. The more stages indicate better control effect, but typically only five or six levels are achievable in practice, resulting in unsatisfactory performance. A preferable control method is PWM-based stepless unloading, which achieves thousands of steps of unloading. In normal unloading operation, the PWM-based stepless unloading method ensures that a battery voltage remains stable at a floating charging voltage point while only surplus energy is dissipated into the unloading devices, thereby ensuring optimal battery charging characteristics and maximizing electrical energy utilization.

As described in the background, link libraries in the conventional technology only correspond to simulation platforms in a one-to-one manner, and the user can only use one simulation platform for simulation, resulting in poor user experience. To address the above issue, a universal system for link libraries, and a method and an apparatus for controlling the universal system for link libraries are provided according to the embodiments of the present disclosure.

The technical solutions of the embodiments of the present disclosure are described clearly and completely below in conjunction with the drawings of the embodiments of the present disclosure.

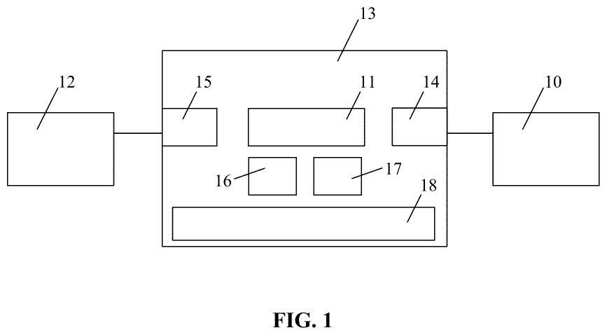

A universal system for link libraries is provided according to the present disclosure. The universal system, as shown in FIG. 1, includes: a workstation 10, multiple simulators 12, and a universal apparatus 13.

The workstation 10 is configured to store multiple link libraries 11. The link library 11 is a collection of library files to be used in a linking process.

The multiple simulators 12 are configured to simulate hardware.

The universal apparatus 13 is communicatively connected to the workstation 10 and the multiple simulators 12. The universal apparatus 13 is configured to invoke any one of the link libraries 11 and send the invoked link library 11 to any one of the simulators 12.

In the universal system, multiple link libraries are combined and multiple simulators are combined. The universal apparatus invokes any one of the link libraries and sends the invoked link library to any one of the simulators, enabling many-to-many configuration between the link libraries and simulation platforms, that is, the link libraries are shared among the simulators. In this way, a user can perform simulation by using different platforms and different link libraries, thereby improving user experience.

At present, renewable energy manufacturers are not motivated to maintain renewable-energy model link libraries for various real-time simulation platforms. Most of the manufacturers provide link libraries for a real-time simulation platform such as RTLAB or ADPSS. A renewable-energy controller link library for a specific real-time simulation platform is used exclusively for the platform and cannot be used for any other real-time simulation platforms. For example, a link library file in a format for RTLAB can be used only for RTLAB but cannot be used for RTDS, HyperSim or ADPSS.

In an embodiment, the above-described universal system is applied to the renewable energy field, and in particular to a photovoltaic controller, a wind turbine controller, or other controllers.

A workstation may be a commonly used computer or another operation platform. The workstation is installed with a Windows operating system and runs RTLink modeling software, and is configured to perform operations such as I/O port mapping for a renewable-energy link library, binding computational tasks to CPU cores, and controlling compilation, running, and monitoring of real-time tasks of a real-time simulator. The workstation communicates with the real-time simulator through Ethernet.

The universal apparatus is configured to transparently forward interface communication data between simulators, for example, RTDS, and renewable-energy link libraries. A single small form pluggable (SPF, optical module) optical port enables full-duplex transmission of sixty-four 32-bit digital signals between the real-time field programmable gate array (FPGA) and the real-time digital simulator (RTDS). The real-time FPGA communicates with a real-time simulator through Gigabit Ethernet in compliance with a custom protocol with optimized real-time performance on the data link layer.

The workstation (also referred to as a command workstation) and a simulator communicate with each other based on the universal apparatus. Specifically, workstation is configured with interfaces to receive and send data. In an implementation, as shown in FIG. 1, the universal apparatus 13 further includes a network interface 14 and an optical fiber interface 15. The universal apparatus 13 is communicatively connected to the workstation 10 through the network interface 14 and receives a link library 11 from the workstation 10 through the network interface 14. The universal apparatus 13 is communicatively connected to the simulators 12 through the optical fiber interface 15.

In the technical solution, a network interface and an optical fiber interface are provided in the universal apparatus. The universal apparatus receives, through the network interface, a link library for a simulator from the workstation, and then sends the link library to the simulator through the optical fiber interface, so that the simulator performs simulation based on the link library, thus enabling communication between link libraries and simulators.

The optical fiber interface may be a commonly used 10-gigabit optical fiber interface for real-time simulators. Generally, an SFP optical interface is adopted. With the SFP optical interface, a real-time simulator communicates with the universal apparatus once within each real-time simulation step.

The workstation and the network interface may communicate with each other through Transmission Control Protocol/Internet Protocol (TCP/IP).

In some embodiments, the above-described link libraries include an RTLAB link library, an ADPSS link library, and a HyperSim link library. The above-described simulators include an RTDS simulator, an RTLAB simulator, an ADPSS simulator, and a HyperSim simulator. In the technical solution, the simulators and link libraries are provided, so that the link libraries are shared among the simulators, instead of one-to-one corresponding configuration between the link libraries and the simulators.

In an embodiment, a renewable-energy controller link library is a dynamic or static link library compiled using logic source codes of a renewable-energy control apparatus.

Through a dynamic link library or a dynamic-link library (abbreviated as DLL), function library sharing is implemented. The file name extensions of function libraries are “.dll”, “.ocx” (for libraries containing ActiveX controls), or “.drv” (for legacy system drivers).

The statically link library, traditionally using lib files, requires the code within the library to be ultimately linked into the executable file. Consequently, the statically linked executable file is generally large. The format of the file is typically expressed as: #pragma comment (lib, “XXX.lib”).

In practice, the universal apparatus may further include a software system configured to better control a simulation process. In an implementation, as shown in FIG. 1, the universal apparatus 13 further includes an RTLinux operating system 16 and a GNU compiler collection (GCC) 17. The RTLinux operating system 16 is configured to provide a set of supporting functions for a hardware real-time process and control a simulation process. The GCC compiler 17 is configured to perform code compilation in conjunction with the above-described RTLinux operating system 16.

In the technical solution, the universal apparatus 13 is further configured with the RTLinux operating system 16 to control the simulation process, enabling users to monitor the simulation process, thereby improving user experience. The GCC compiler 17 is configured to perform compilation of program codes in the simulation process in conjunction with the RTLinux operating system 16. Thus, a compiled link library may be directly sent to a simulator for running.

The universal apparatus may be configured with an x86-64-based real-time Linux operating system for running a renewable-energy control and protection link library in a real-time manner. The universal apparatus is configured with 4 SFP optical ports for real-time co-simulation with simulators such as RTDS.

A free and open-source real-time Linux operating system is adopted, with the Linux real-time kernel patch preempt_rt installed. Through a series optimizations such as, boot parameter tuning, manual kernel interrupt affinity assignment, real-time task priority adjustment, and memory pre-allocation, the jitter of real-time tasks is significantly reduced, ensuring real-time performance of the real-time tasks. Tests demonstrate that, for a 50 us simulation step, the long-term runtime jitter remains within 5 us. The real-time Linux operating system adopts the Intel x86-64 architecture and supports loading and running of both 32-bit and 64-bit renewable-energy control and protection link libraries. The commonly used control and protection link libraries such as the static library (a) files in the RTLAB platform and the (.so) files in the ADPSS platform are all built based on the Intel x86-64 architecture and therefore may be run directly without additional compilation.

In an embodiment, RTLink modeling software runs on a command workstation to perform operations such as I/O port mapping for a renewable-energy link library, binding computational tasks to CPU cores, and operations such as controlling compilation, running, monitoring, and waveform recording for real-time tasks of a real-time simulator. The RTLink modeling software communicates with the real-time simulator through Ethernet.

In an embodiment, as shown in FIG. 1, the universal apparatus 13 further includes hardware 18, such as a storage device, a memory, or a hard disk.

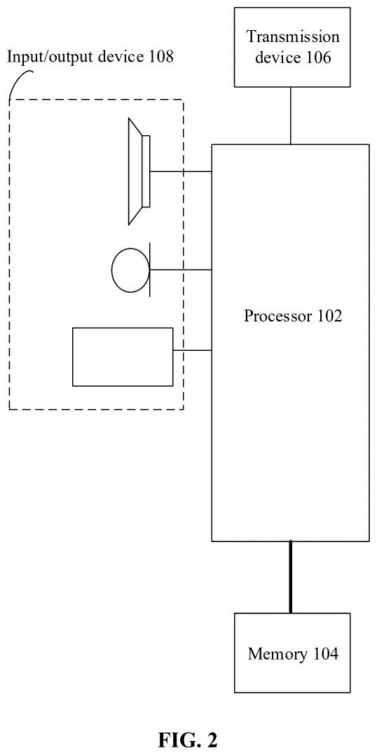

Embodiments of the method provided according to the present disclosure may be implemented on a mobile terminal, a computer terminal, or a similar computing apparatus. Taking the implementation on a mobile terminal as an example, FIG. 2 is a structural block diagram of hardware of the mobile terminal for implementing a method for controlling a universal system for link libraries according to an embodiment of the present disclosure. As shown in FIG. 2, the mobile terminal may include one or more (only one is shown in FIG. 2) processors 102, and a memory 104 for storing data. The processor 102 may include, but is not limited to, a processing apparatus such as a microprocessor MCU or a programmable logic device FPGA. The mobile terminal may further include a transmission device 106 for communication and an input/output device 108. Those skilled in the art may understand that the structure shown in FIG. 2 is only illustrative and does not constitute a limitation to the structure of the above-described mobile terminal. For example, the mobile terminal may include more or fewer components than those shown in FIG. 2, or have a different configuration from that shown in FIG. 2.

The memory 104 stores a computer program, such as a software program and a module of an application. The computer program may include a computer program corresponding to the device information display method described in the embodiments of the present disclosure. The processor 102 executes various functional applications and performs data processing by executing the computer program stored in the memory 104, thereby implementing the above-described method. The memory 104 may include a high-speed random-access memory, and may further include a non-volatile memory, such as one or more magnetic disk storage apparatuses, a flash memory, or another non-volatile solid memory. In some embodiments, the memory 104 further includes a memory remotely disposed relative to the processor 102, and the remote memory is connected to the mobile terminal through a network. The network may include, but is not limited to, the Internet, an intranet, a local area network, a mobile communication network, or a combination thereof. The transmission device 106 is configured to receive or send data through a network. In an embodiment, the network includes a wireless network provided by a communication provider of the mobile terminal. In an embodiment, the transmission device 106 includes a network interface controller (abbreviated as NIC). The NIC may be configured to connect to other network devices through a base station, so as to communicate with the Internet. In an embodiment, the transmission device 106 is a radio frequency (RF) module configured to wirelessly communicate with the Internet.

A method for controlling a universal system for link libraries is provided according to an embodiment of the present disclosure. The universal system may run on a mobile terminal, a computer terminal, or a similar computing apparatus. It should be noted that the steps shown in the flowchart in the accompanying drawings may be implemented as a set of computer-executable instructions in a computer system. Although a logical order is shown in the flowchart, in some cases, the steps may be performed in a different order from that shown or described herein.

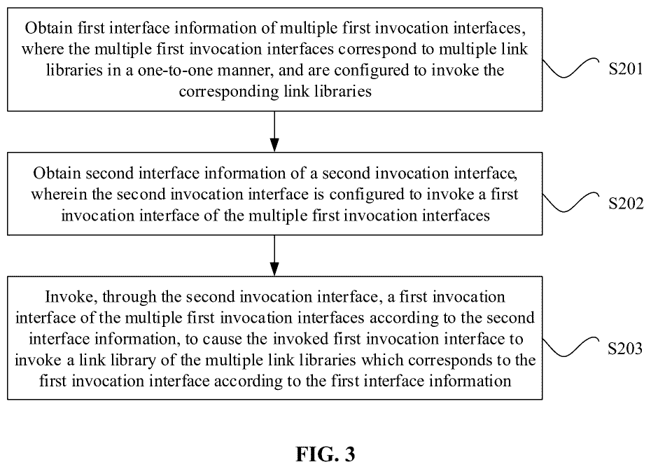

FIG. 3 is flowchart of a method for controlling a universal system for link libraries according to an embodiment of the present disclosure. As shown in FIG. 3, the method includes the following steps S201 to S203.

In step S201, first interface information of multiple first invocation interfaces is obtained. The first invocation interfaces correspond to the above-described link libraries in a one-to-one manner, and are configured to invoke the corresponding link libraries.

In an embodiment, specific wrapper invocation programs are developed for link libraries of platforms such as RTLAB, ADPSS, and HyperSim, that is, first invocation interfaces corresponding to different link libraries are developed.

In step S202, second interface information of a second invocation interface is obtained. The second invocation interface is configured to invoke a first invocation interface of the first invocation interfaces.

In an embodiment, the second invocation interface is compiled, and the first invocation interface is invoked through the second invocation interface, to achieve real-time invocation of link libraries of different platforms.

In step S203, the first invocation interface is invoked through the second invocation interface according to the second interface information, to cause the invoked first invocation interface to invoke a link library of the link libraries which corresponds to the first invocation interface according to the first interface information.

In an embodiment, the second invocation interface implements real-time scheduling and running of the link libraries to realize real-time invocation of the link libraries of different platforms.

In the embodiment, any one of the first invocation interfaces is invoked through the second invocation interface, and the link library corresponding to the invoked first invocation interface is invoked through the first invocation interface. Thus, any link library can be invoked through the second invocation interface and then sent to a simulator, enabling many-to-many configuration between the link libraries and simulation platforms, that is, the link libraries are shared among the simulators. In this way, a user can perform simulation by using different platforms and different link libraries, thereby improving user experience.

In an embodiment, an optical fiber interface is configured to implement real-time communication of a real-time simulator, enabling real-time simulation operation of mainstream simulators such as RTDS, RTLAB, ADPSS, and HyperSim.

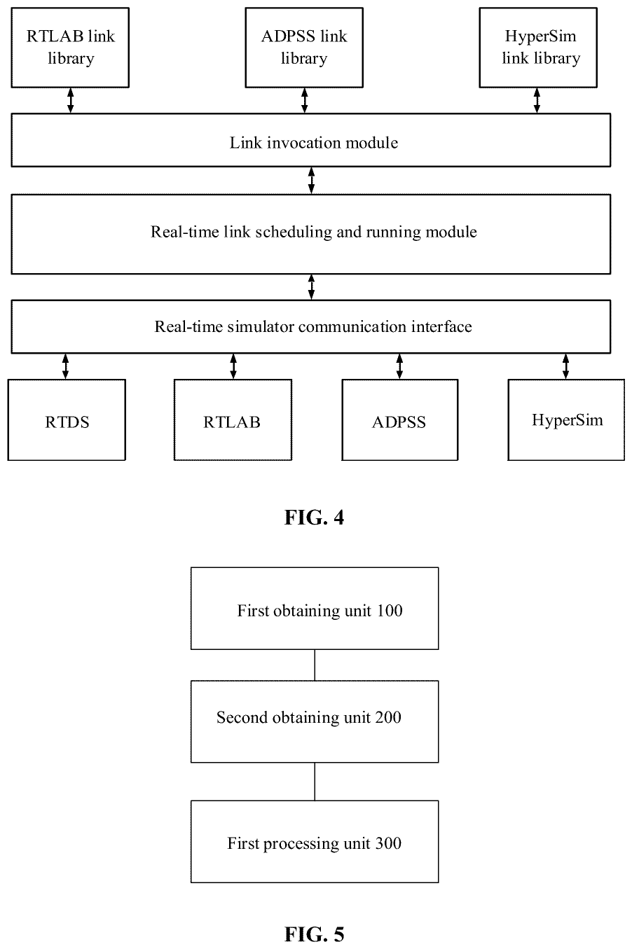

In an embodiment, FIG. 4 shows software logic of the above-described universal system. In view of the software logic, the universal system includes a link invocation module, a link real-time scheduling and running module, a real-time simulator communication interface, multiple link libraries, and multiple simulators. Arrows between the link invocation module and the link libraries indicate first invocation interfaces and a network interface. The link real-time scheduling and running module is configured to invoke a second invocation interface. The real-time simulator communication interface is an optical fiber interface for communicating with the simulators.

The second invocation interface serves as an invocation compatibility layer that provides a same invocation interface for different types of link libraries, where invocation interfaces for RTLAB, ADPSS and HyperSim may be different. For specific implementation, C codes are dynamically generated for modules for invoking different types of link libraries, and then GCC is invoked to compile the C codes into an executable file.

Whether there is one link library or multiple, invoking them serves to implement a task. A task scheduling list may be constructed to schedule link libraries according to tasks in the task scheduling list. In an implementation, after obtaining the second interface information of the second invocation interface, the method further includes: obtaining a task scheduling list, where the task scheduling list includes multiple tasks and each of the tasks includes a pre-invoked link library of the multiple link libraries; and traversing the task scheduling list and executing the tasks in order.

In the technical solution, multiple tasks are executed in order according to the task scheduling list. Each time a task is executed, a link library is invoked once so that the link library to be linked runs for the current simulation, thereby ensuring that an invocation process is under control and an invocation order is appropriate.

In an embodiment, a timer and a task scheduling list are configured in a universal apparatus. The link libraries have different scheduling and running periods, and all the periods are integer multiples of a real-time simulation step size. Each time the timer completes a real-time simulation step, the task scheduling list is traversed so that a link library required for the current simulation step runs in a real time manner.

Further, task scheduling may be implemented by a real-time task scheduler. The real-time task scheduler RTLinkD is a program running in the background in a non-real-time manner. The RTLinkD is configured to receive and execute an instruction for compilation, running, or terminating a link library sent from a command workstation. The RTLinkD is developed using GoLang, a programming language well-suited for building network-concurrent programs, and is registered as a systemctl service in Linux. The RTLinkD is configured to: launch automatically on system startup, run persistently in the background, and automatically restart upon abnormal termination detected to ensure long-term stable operation of the RTLinkD.

To efficiently and accurately execute multiple tasks, executing the tasks in order according to the present disclosure may be performed by: obtaining priorities of the multiple tasks, and executing the multiple tasks in a descending order of priority; and obtaining an association relationship among the multiple tasks, and executing the multiple tasks in order according to the association relationship. The association relationship includes a serial relationship and a parallel relationship, the serial relationship indicates that the multiple tasks are sequentially executed, and the parallel relationship indicates that the multiple tasks are executed in parallel.

In the technical solution, the association relationship between multiple tasks may be determined. The association relationship may include the serial relationship and the parallel relationship so that the tasks may be executed sequentially or in parallel, respectively. Thus, the tasks are efficiently and accurately executed according to the association relationship and according to the priorities thereof, thereby avoiding scheduling problems among the tasks.

In a simulation process, a simulator may become abnormal, and therefore it may be detected whether the simulator is abnormal. In some embodiments, after the invoking, through the second invocation interface, a first invocation interface of the multiple first invocation interfaces according to the second interface information, to cause the invoked first invocation interface to invoke a link library of the multiple link libraries which corresponds to the first invocation interface according to the first interface information, the method further includes: controlling a simulator receiving the invoked link library to perform simulation; and determining that the simulator is abnormal in a case that no response is received from the simulator within a predetermined duration.

In the technical solution, in the simulation process using the link library and the simulator, the simulator returns a response message no matter whether the simulator receives a link library file or the simulation is completed. From a time instant when the link library is sent to the simulator, if no response is returned within a predetermined duration/timeout period, it is determined that the simulator is abnormal, thereby implementing anomaly detection on the simulator. In this way, a subsequent simulation failure caused by the simulator not responding for a long time period is prevented, improving simulation efficiency.

In an embodiment, the predetermined duration may be 50 us or another predetermined duration.

During invocation of a link library, the invocation may be terminated in response to an instruction of a user. In some embodiments, after the invoking, through the second invocation interface, a first invocation interface of the multiple first invocation interfaces according to the second interface information, to cause the invoked first invocation interface to invoke a link library of the multiple link libraries which corresponds to the first invocation interface according to the first interface information, the method further includes: terminating the invocation of the link library upon receiving a termination command, where the termination command is generated by the workstation.

In the technical solution, the workstation may send the termination command. The invocation of the link library is terminated on receipt of the termination command. In this way, users can control the invocation of the link library, thereby improving user experience.

In an embodiment, on receipt of a start command, a link library is invoked in response to the start command. The start command is generated by the workstation.

In an embodiment, an operating process of the above-described universal system is as follows. The workstation sends link libraries of platforms such as RTDS and ADPSS to the universal apparatus through a network protocol such as Hypertext Transfer Protocol (HTTP). A memory-resident service program in the universal apparatus generates respective specific C-language invocation codes for the link libraries of the platforms and provides a unified link library invocation interface (the second invocation interface). The C-language codes are compiled into the first invocation interfaces by using GCC. A first invocation interface of the first invocation interfaces is invoked through the second invocation interface, to cause the invoked first invocation interface to invoke a link library of multiple link libraries which corresponds to the first invocation interface according to the first interface information.

The following introduces a process of configuring the universal apparatus and running software for the renewable-energy control and protection link libraries.

### 1.1 Creating an RTLink Project

Right-click a blank area in a left workspace.->Select “Create”.>Select “RTLink Project”. Enter a project name in a pop-up dialog box, and then click OK to create a project. The created project does not include any link library.

### 1.2 Setting Project Sampling Time

Double-click a to-be-configured project in a left workspace. Then open a project window on the right pane of the workspace, and enter a project sampling time in us. The project sampling time is set to be consistent with an RTDS simulation step size.

### 1.3 Importing a Link Library

Right-click on the project.->Select “Import Link Library”, or, right-click on a project link library folder.->Select “Import Link Library”. Then select a link library to be imported in a pop-up dialog box. Alternatively, drag and drop the link library file directly onto the project link library folder icon.

After the link library is successfully imported, different icons are displayed depending on the situation, for example, an icon of a 64-bit link library or an icon of 32-bit link library may be displayed. The functions are listed under the libraries, and may be displayed whether they are 32-bit or 64-bit.

### 1.4 Resolving the Link Library

Resolving the link library refers to obtaining information such as the quantity and dimension of input ports and output ports of the function. It requires an online real-time simulator to resolve the link library. No further operation is allowed on the link library before the link library is resolved. A red question mark is displayed on the function icon of an unresolved link library.

When a link library is being imported, if a real-time simulator is online, the real-time simulator automatically resolves the link library; and if no real-time simulator is online, the link library is not automatically resolved. If a real-time simulator is online after the link library is imported, the link library is not automatically resolved. In such case, the link library is required to be manually resolved. To manually resolve the link library, the following operations are performed: Right-click on the link library folder.->Select “Resolve Link Library”, and thus unresolved link libraries of the current project are resolved. Alternatively, right-click on a single link library.->Select “Resolve Link Library”, and thus only the single link library is resolved.

### 1.5 Viewing Link Library Information

Double-click on a resolved link library to open a link library viewing window, Information displayed in the window includes the quantity and dimension of the input ports and output ports, the quantity of dialog box parameters, a sampling period and other information of the link library. By default, function ports are assigned meaningless names: input ports begin with “In”, and output ports begin with “Out”. A user may double-click a name to change it to a meaningful name, facilitating viewing a recording channel and observing input and output variable values of the link library in real time.

### 1.6 Setting a Target Real-Time Simulator

Drag and drop a simulator on a real-time simulator to an icon of a target simulator in the project folder. After the operation is successful, the name of the real-time simulator is displayed on the right side of the target simulator.

1.7 Setting a Quantity of to-be-Used CPUs of the Real-Time Simulator

By default, the target real-time simulator uses 6 CPUs. To set the quantity of the CPUs, right-click on the target simulator->Set the quantity of CPUs to be used. The quantity depends on actual needs and cannot exceed the quantity of authorized CPUs of the real-time simulator.

### 1.8 Allocating CPU Computing Tasks

Allocating CPU computing tasks refers to a process of allocating functions in a link library to a CPU. To allocate a function, the function listed under a link library is dragged and dropped to a CPU. One CPU may be allocated with multiple function instances. Function instances are allocated to CPUs as evenly as possible.

It should be noted that 32-bit link library functions and 64-bit link library functions are required to be allocated to different CPUs for computing.

### 1.9 Configuration of Input Port and Output Port Mapping for Link Library Functions

Configuration of input port and output port mapping for link library functions refers to a process of mapping the input and output ports of the link library functions allocated to the CPUs to communication channels of physical optical ports. On the RTDS side, each of the physical optical ports corresponds to one GTFPGA module. Each GTFPGA module bidirectionally transmits 64 32-bit integers or floating-point numbers at each step.

The functions allocated to the CPUs are double-clicked to access a link library function port mapping interface. On the interface, it is required to set an optical port number, a channel number, and a channel type for each input port and each output port of the link library. Each optical port number corresponds to one physical SFP optical port. Currently, the platform supports a maximum of 4 optical ports, defining a valid range of the optical port number to be 1 to 4. The channel number refers to that of the GTFPGA module on the RTDS side, with a valid range of 1 to 64. The channel type refers to that of the GTFPGA module on the RTDS side, such as float and int. Channel types of the GTFPGA module on the RTDS side are configured to be consistent. It should be noted that a port number or a channel number set to 0 indicates that the port is considered unused, and thus for input ports, the input value is always 0; for output ports, any output value is meaningless.

### 1.9.1 Quickly Setting Port Information

In normal cases, the setting includes directly double-clicking or clicking an optical port number or a channel number, and then modifying the number by using a keyboard. For regular optical port numbers and channel numbers, port information may be quickly set using the following methods.

### (1) Batch Setting to a Same Value

Drag the pointer to select optical port numbers or channel numbers of multiple channels by using the mouse, and then right-click and select “Setting”. Enter port numbers or channel numbers in a pop-up dialog box. Alternatively, drag the pointer to select optical port numbers or channel numbers of multiple channels, and then right-click and select “Set to 0 (or other values)”. Then, drag the pointer to select channel types of multiple channels, and then select “Set to Int” or “Set to Float”.

### (2) Batch Setting to Incremental Values

Manually set two consecutive port numbers or channel numbers in an arithmetic sequence (for example, 1 and 2). Then, select the two consecutive numbers, right-click the selected area, and then select Increment. In a pop-up dialog box, enter an increment count (for example, 10). Subsequent values, that is, 3 to 12, are automatically filled. This method is particularly applicable to setting consecutive sequential channel numbers.

### (3) Batch Setting to Incremental Values

Drag the pointer to batch select multiple optical port numbers, channel numbers, or channel types, and then right-click the selected area. In the pop-up shortcut menu, select “Copy”. Then, right-click on an area to which the copied settings are to be pasted. In the pop-up menu, select “Paste”.

### 1.9.2 Port Multiplexing Configuration

The input ports and output ports of many link libraries use binary signals with only two possible states (0 or 1). Using a full 32-bit integer channel to transmit a single binary signal wastes limited channel resources. The RTLink supports mapping multiple binary I/O signals to individual bits within a same integer channel. To configure port multiplexing, right-click on a channel type, and then select “Set as Int Low N bit”. The method significantly optimizes channel utilization.

### 1.9.3 Port Time-Division Multiplexing Configuration

Assuming that a sampling time of the project is 50 us and a function sampling time of the link library is 250 us, the link library runs only once every 5 simulation steps on the RTDS side. During the 4 intermediate simulation steps, the link library is inactive and transmitted data is unused, resulting in waste of channel resources. If 5 link library function instances are required to run, inputs and outputs of one of the 5 link library function instances are transmitted during each simulation step. In this way, channels allocated to one link library transmit inputs and outputs of 5 link libraries in a time-multiplexing manner, drastically reducing channel consumption. To distinguish between different link library function instances, a dedicated input channel and a dedicated output channel are required to respectively carry link library function instance IDs during transmission.

For port time-division multiplexing configuration, the following operations are performed: On an interface for configuration of input/output port mapping of link library functions, select “Port time-division multiplexing”, set the quantity of instances for which port multiplexing is to be configured, and then specify an optical port number and a channel number of a channel corresponding to an instance ID in the input/output port mapping settings. In addition, develop logic on the RTDS side so that data of different instances is inputted and outputted according to the instance ID.

### 1.10 Compiling and Executing the RTLink Project

A dialog box for the project may be displayed.

### 1.10.1 Building and Running

Double-click the project. An interface including the “Build”, “Execute”, and “Terminate” buttons that respectively control compilation, running, and termination of the link library are displayed in the Ribbon area. It is noted that an RTDS model runs first and then a link library model runs.

### 1.10.2 Waveform Recording

The RTLink is capable of waveform recording for all the input ports and output ports of a link library function instance. For implementing waveform recording, the following operations are performed: Control a link library project model to run, and then double-click a link library function instance under the CPU. On the displayed input/output port mapping modeling interface, set an appropriate waveform recording time. Then, click to trigger recording waveform.

The following verifies the universal platform for the renewable-energy control and protection link libraries.

### 2.1 Comparative Testing

A dynamic link library for a 12MW direct-drive wind turbine is adopted for the test. According to test categories specified by relevant standards, simulation tests and comparative analysis are performed within power ranges and fault conditions listed in Table 1. Analysis results are listed in Table 1.

TABLE 1
Simulation test results

| | | | Fault |
|---|---|---|---|
| No. | Power Range | Fault Condition | Duration (s) |
| 1 | Low-power | Three-phase voltage dip: 0.2p.u. | 0.625 |
| 2 | output state | Three-phase voltage dip: 0.35p.u. | 0.93 |
| 3 | 0.1Pn ≤ | Three-phase voltage dip: 0.5p.u. | 1.22 |
| 4 | P ≤ 0.3Pn | Three-phase voltage dip: 0.75p.u. | 1.71 |
| 5 | | Three-phase voltage dip: 0.9p.u. | 2 |
| 6 | | Three-phase voltage swell: 1.2p.u. | 10 |
| 7 | | Three-phase voltage swell: 1.25p.u. | 1 |
| 8 | | Three-phase voltage swell: 1.3p.u. | 0.5 |
| 9 | High-power | Three-phase voltage dip: 0.2p.u. | 0.625 |
| 10 | output state | Three-phase voltage dip: 0.35p.u. | 0.93 |
| 11 | P ≥ 0.9Pn | Three-phase voltage dip: 0.5p.u. | 1.22 |
| 12 | | Three-phase voltage dip: 0.75p.u. | 1.71 |
| 13 | | Three-phase voltage dip: 0.9p.u. | 2 |
| 14 | | Three-phase voltage swell: 1.2p.u. | 10 |
| 15 | | Three-phase voltage swell: 1.25p.u. | 1 |
| 16 | | Three-phase voltage swell: 1.3p.u. | 0.5 |

For different channels, the measurands are different. The measurands for the channels are listed in Table 2.

TABLE 2
Channel measurands

| Channel | Unit | Measurand |
|---|---|---|
| 1 | p.u. | Fundamental |
| | | positive-sequence voltage |
| 2 | p.u. | Active power |
| 3 | p.u. | Reactive power |
| 4 | p.u. | Reactive current |

The following is a comparison of simulation fault data for the dynamic link library for the 12MW direct-drive wind turbine under different fault conditions at high and low power levels. The blue curve shows the simulation test result of dynamic link library invocation by MATLAB, and the red curve shows the co-simulation test result of dynamic link library invocation by RTDS and RTLink.

### 3.1.1 Simulation Test Results at Low Power

Simulation test results at low power are obtained based on the above description.

### 3.1.2 Simulation Test Results at Low Power

Simulation test results at high power are obtained based on the above description.

In summary, to verify the accuracy of the platform, a comparative analysis is performed on a dynamic link library for a 12MW direct-drive wind turbine under both high and low power conditions. The results demonstrate that the high/low voltage ride-through characteristics obtained through co-simulation with the RTDS closely match those obtained through MATLAB offline simulation, proving the feasibility and accuracy of the platform.

An apparatus for controlling a universal system for link libraries is provided according to an embodiment of the present disclosure. It should be noted that the apparatus may be configured to perform the method for controlling the universal system for the link libraries according to the embodiments of the present disclosure. The apparatus is configured to implement the above-described embodiments and preferred embodiments, and the description thereof is not repeated. The term “module” used hereinafter is capable of implementing a predetermined function in software and/or combined with hardware. Although the apparatus described in the following embodiments is preferably implemented using software, an implementation using hardware, or a combination of software and hardware, is possible and considered.

The following describes the apparatus for controlling the universal system for link libraries according to an embodiment of the present disclosure.

FIG. 5 is a structural block diagram of an apparatus for controlling a universal system for link libraries according to an embodiment of the present disclosure. As shown in FIG. 5, the apparatus includes: a first obtaining unit 100, a second obtaining unit 200 and a first processing unit 300.

The first obtaining unit 100 is configured to obtain first interface information of multiple first invocation interfaces. The first invocation interfaces 100 correspond to multiple link libraries in a one-to-one manner and are configured to invoke the corresponding link libraries.

The second obtaining unit 200 is configured to configured to obtain second interface information of a second invocation interface. The second invocation interface is configured to invoke a first invocation interface of the multiple first invocation interfaces.

The first processing unit 300 is configured to invoke, through the second invocation interface, a first invocation interface of the multiple first invocation interfaces according to the second interface information, to cause the invoked first invocation interface to invoke a link library of the multiple link libraries which corresponds to the first invocation interface according to the first interface information.

In the embodiment, any one of the first invocation interfaces is invoked through the second invocation interface, and the link library corresponding to the invoked first invocation interface is invoked through the first invocation interface. Thus, any link library can be invoked through the second invocation interface and then sent to a simulator, enabling many-to-many configuration between the link libraries and simulation platforms, that is, the link libraries are shared among the simulators. In this way, a user can perform simulation by using different platforms and different link libraries, thereby improving user experience.

Whether there is one link library or multiple, invoking them serves to implement a task. A task scheduling list may be constructed to schedule link libraries according to tasks in the task scheduling list. In an implementation, the apparatus further includes a third obtaining unit and a second processing unit. The third obtaining unit is configured to, after the second interface information of the second invocation interface is obtained, obtain a task scheduling list, where the task scheduling list includes multiple tasks and each of the tasks includes a pre-invoked link library of the multiple link libraries. The second processing unit is configured to traverse the task scheduling list and execute the tasks in order.

In the technical solution, multiple tasks are executed in order according to the task scheduling list. Each time a task is executed, a link library is invoked once so that the link library to be linked runs for the current simulation, thereby ensuring that an invocation process is under control and an invocation order is appropriate.

To efficiently and accurately execute multiple tasks, the second processing unit according to the present disclosure includes a first processing module and a second processing module. The first processing module is configured to obtain priorities of the multiple tasks and execute the multiple tasks in a descending order of priority. The second processing module is configured to obtain association relationship among the multiple tasks, and execute the multiple tasks in order according to the association relationship. The association relationship includes a serial relationship and a parallel relationship, the serial relationship indicates that the multiple tasks are sequentially executed, and the parallel relationship indicates that the multiple tasks are executed in parallel.

In the technical solution, the association relationship between multiple tasks may be determined. The association relationship may include the serial relationship and the parallel relationship so that the tasks may be executed sequentially or in parallel, respectively. Thus, the tasks are efficiently and accurately executed according to the association relationship and according to the priorities thereof, thereby avoiding scheduling problems among the tasks.

In a simulation process, a simulator may be abnormal, and therefore it may be detected whether the simulator is abnormal. In some embodiments, the apparatus includes a control unit and a determination unit. The control unit is configured to, after the first invocation interface of the multiple first invocation interfaces is invoked through the second invocation interface according to the second interface information, to cause the invoked first invocation interface to invoke a link library of the multiple link libraries which corresponds to the first invocation interface according to the first interface information, control a simulator receiving the invoked link library to perform simulation. The determination unit is configured to determine that the simulator is abnormal in a case that no response is received from the simulator within a predetermined duration.

In the technical solution, in the simulation process using the link library and the simulator, the simulator returns a response message no matter whether the simulator receives a link library file or the simulation is completed. From a time instant when the link library is sent to the simulator, if no response is returned within a predetermined duration/timeout period, it is determined that the simulator is abnormal, thereby implementing anomaly detection on the simulator. In this way, a subsequent simulation failure caused by the simulator not responding for a long time period is prevented, improving simulation efficiency.

During invocation of a link library, the invocation may be terminated in response to an instruction of a user. In some embodiments, the apparatus includes a third processing unit. The third processing unit is configured to: after the first invocation interface of the multiple first invocation interfaces is invoked through the second invocation interface according to the second interface information, to cause the invoked first invocation interface to invoke a link library of the multiple link libraries which corresponds to the first invocation interface according to the first interface information, terminate the invocation of the link library upon receiving a termination command, where the termination command is generated by the workstation.

In the technical solution, the workstation may send the termination command. The invocation of the link library is terminated on receipt of the termination command. In this way, users can control the invocation of the link library, thereby improving user experience.

The above-described apparatus for controlling the universal system for the link libraries may include a processor and a memory. The above-described first obtaining unit, the second obtaining unit, and the first processing unit are stored in the memory as program units. The processor executes the program units stored in the memory to implement corresponding functions. The above-described modules may be configured in the same processor or configured in any combination in different processors.

The processor includes a core, and the core is configured to invoke the program unit from the memory. The core may be one or more in quantity. Link libraries in the conventional technology are configured to correspond to simulation platforms only in a one-to-one manner and users can use only one simulation platform for simulation, resulting in poor user experience. The issue can be addressed by adjusting parameters of the core.

The memory may include a non-persistent memory, a random access memory (RAM), and/or a non-volatile memory in computer-readable media, such as read-only memory (ROM) or flash RAM. The memory includes at least one storage chip.

A computer-readable storage medium is provided according to an embodiment of the present disclosure. The computer-readable storage medium stores a computer program that is configured to, when being executed, control a device where the computer-readable storage medium is arranged to perform the method for controlling the universal system for the link libraries.

A processor is provided according to an embodiment of the present disclosure. The processor is configured to, when executing a program, perform the method for controlling the universal system for the link libraries.

A device is provided according to an embodiment of the present disclosure. The device includes a processor, a memory, and a program stored in the memory and executable on the processor. The processor is configured to, when executing the program, perform the method for controlling the universal system for the link libraries.

A computer program product is provided according to an embodiment of the present disclosure. The computer program product is configured to, when being executed on a data processing device, initialize a program that includes steps of the method for controlling the universal system for the link libraries.

Apparently, those skilled in the art should understand that the above-described modules and steps according to the present disclosure may be implemented by a universal computing apparatus. The modules and steps may be centrally configured on a single computing apparatus, or distributed over a network including multiple computing apparatus. The modules and steps may be implemented using program codes executable by a computing apparatus, thereby allowing them to be stored in a storage apparatus for execution by the computing apparatus. In some cases, the steps illustrated or described herein may be executed in order different from that presented, or the modules and steps may be fabricated as separate integrated circuit modules. Alternatively, multiple modules or steps may be combined into a single integrated circuit module for implementation. Thus, the present disclosure is not limited to any specific combination of hardware and software.

Those skilled in the art should understand that the embodiments of the present disclosure may be provided as a method, a system, or a computer program product. Therefore, the present disclosure may adopt the form of a complete hardware embodiment, a complete software embodiment, or an embodiment combining hardware and software. In addition, the present disclosure may be implemented in a form of a computer program product that is implemented in one or more computer-usable storage media (including but not limited to a disk memory, a CD-ROM, an optical memory and the like) storing computer-usable program codes.

The present disclosure is described with reference to flow charts and/or block diagrams of the method, the device (system), and the computer program product according to the embodiments of the present disclosure. It should be understood that each flow and/or block in the flowcharts and/or block diagrams and a combination of flows and/or blocks in the flowcharts and/or block diagrams may be implemented by computer program instructions. The computer program instructions may be provided to a universal computer, a dedicated computer, an embedded processor or processors of other programmable data processing devices to generate a machine, such that the instructions executed by the computer or the processors of the other programmable data processing devices generate an apparatus for implementing functions specified in one or more flows in the flowcharts and/or one or more blocks in the block diagrams.

The computer program instructions may also be stored in a computer-readable memory which can guide the computer or other programmable data processing devices to operate in a certain manner, such that the instructions stored in the computer-readable memory generate a product including an instruction apparatus which implements the functions specified in one or more flows in the flowcharts and/or one or more blocks in the block diagrams.

The computer program instructions may also be loaded onto the computer or other programmable data processing devices, so that the computer or the other programmable data processing devices perform a series of operations to perform computer-implemented processing. Thus, instructions executed on the computer or the other programmable devices provide steps for implementing the functions specified in one or more flows in the flowcharts and/or one or more blocks in the block diagrams.

In a typical configuration, the computing apparatus includes one or more processors (CPUs), an input/output interface, a network interface, and a memory.

The memory may include a non-persistent memory, a random access memory (RAM), and/or a non-volatile memory in computer-readable mediums, such as read-only memory (ROM) or flash RAM. The memory is an example of the computer readable media.

A computer readable medium may include a persistent and non-persistent medium, and a removable and non-removable medium. Information may be stored based on any method or technology. The information may be computer-readable instructions, a data structure, a program module, or other data. The computer storage medium includes, but is not limited to, a phase change memory (PRAM), a static random access memory (SRAM), a dynamic random access memory (DRAM), other types of random access memories (RAMs), a read-only memory (ROM), an electrically erasable programmable read-only memory (EEPROM), a flash memory or other memory technologies, a compact disk read only memory (CD-ROM), a digital versatile disk (DVD) or other optical memories, a magnetic cassette tape, a magnetic tape and magnetic disk storage, other magnetic storage devices, or any other non-transmission medium capable of storing information that can be accessed by a computing apparatus. According to the definition of the present disclosure, the computer readable medium does not include transitory media, such as a modulated data signal and a carrier.

It should be noted that the terms “comprise”, “include”, or any other variants thereof are intended to encompass a non-exclusive inclusion, such that a process, method, article, or device including a series of elements includes not only those elements but also elements that are not explicitly listed, or elements that are inherent to such process, method, article, or device. Unless expressively limited otherwise, a process, method, article or device limited by “comprising/including a (n).” does not exclude existence of other identical elements in such process, method, article or device.

From the above description, it can be seen that the above embodiments of the present disclosure can achieve the following technical effects.

1) In the universal system for the link libraries according to the present disclosure, multiple link libraries are combined and multiple simulators are combined. A universal apparatus is configured to invoke any one of the link libraries and send the invoked link library to any one of the simulators, enabling many-to-many configuration between the link libraries and simulation platforms, that is, the link libraries are shared among the simulators. In this way, a user can perform simulation by using different platforms and different link libraries, thereby improving user experience.

2) With the method for controlling the universal system for the link libraries, any one of the first invocation interfaces is invoked through the second invocation interface, and the link library corresponding to the invoked first invocation interface is invoked through the first invocation interface. Thus, any link library can be invoked through the second invocation interface and then sent to a simulator, enabling many-to-many configuration between the link libraries and simulation platforms, that is, the link libraries are shared among the simulators. In this way, a user can perform simulation by using different platforms and different link libraries, thereby improving user experience.

3) With the apparatus for controlling the universal system for the link libraries, any one of the first invocation interfaces is invoked through the second invocation interface, and the link library corresponding to the invoked first invocation interface is invoked through the first invocation interface. Thus, any link library can be invoked through the second invocation interface and then sent to a simulator, enabling many-to-many configuration between the link libraries and simulation platforms, that is, the link libraries are shared among the simulators. In this way, a user can perform simulation by using different platforms and different link libraries, thereby improving user experience.

The above is only preferred embodiments of the present disclosure and is not intended to limit the present disclosure. For those skilled in the art, the present disclosure may have various modifications and changes. Any modifications, equivalent replacements and improvements made within the principle of the present disclosure shall be within the protection scope of the present disclosure.

1. A universal system for link libraries, comprising:
a workstation, configured to store a plurality of link libraries, wherein each of the plurality of link libraries is a collection of library files to be used in a linking process;
a plurality of simulators, configured to simulate hardware; and
a universal apparatus, wherein the universal apparatus is communicatively connected to the workstation and the plurality of simulators, and is configured to invoke any one of the plurality of link libraries and send the invoked link library to any one of the plurality of simulators.

2. The universal system according to claim 1, wherein the universal apparatus comprises:
a network interface, wherein the universal apparatus is communicatively connected to the workstation through the network interface, and is configured to receive the invoked link library from the workstation through the network interface; and
an optical fiber interface, wherein the universal apparatus is communicatively connected to the plurality of simulators through the optical fiber interface.

3. The universal system according to claim 1, wherein
the plurality of link libraries comprise an RTLAB link library, an ADPSS link library, and a HyperSim link library, and
the plurality of simulators comprise an RTDS simulator, an RTLAB simulator, an ADPSS simulator, and a HyperSim simulator.

4. The universal system according to claim 1, wherein the universal apparatus comprises:
an RTLinux operating system, configured to provide a set of supporting functions for a hardware real-time process and control a simulation process; and
a GCC compiler, configured to perform code compilation in conjunction with the RTLinux operating system.

5. A method for controlling the universal system for link libraries according to claim 1, comprising:
obtaining first interface information of a plurality of first invocation interfaces, wherein the plurality of first invocation interfaces correspond to the plurality of link libraries in a one-to-one manner, and are configured to invoke the corresponding link libraries;
obtaining second interface information of a second invocation interface, wherein the second invocation interface is configured to invoke a first invocation interface of the plurality of first invocation interfaces; and
invoking, through the second invocation interface, a first invocation interface of the plurality of first invocation interfaces according to the second interface information, to cause the invoked first invocation interface to invoke a link library of the plurality of link libraries which corresponds to the first invocation interface according to the first interface information.

6. The method according to claim 5, wherein after the obtaining second interface information of a second invocation interface, the method further comprises:
obtaining a task scheduling list, wherein the task scheduling list comprises a plurality of tasks, each of the plurality of tasks comprises a pre-invoked link library of the plurality of link libraries; and
traversing the task scheduling list and executing the plurality of tasks in order.

7. The method according to claim 6, wherein the executing the plurality of tasks in order comprises:
obtaining priorities of the plurality of tasks, and executing the plurality of tasks in a descending order of priority; and
obtaining an association relationship among the plurality of tasks, and executing the plurality of tasks in order according to the association relationship, wherein the association relationship comprises a serial relationship and a parallel relationship, the serial relationship indicates that the plurality of tasks are sequentially executed, and the parallel relationship indicates that the plurality of tasks are executed in parallel.

8. The method according to claim 5, wherein after the invoking, through the second invocation interface, a first invocation interface of the plurality of first invocation interfaces according to the second interface information, to cause the invoked first invocation interface to invoke a link library of the plurality of link libraries which corresponds to the first invocation interface according to the first interface information, the method further comprises:
controlling a simulator receiving the invoked link library to perform simulation; and
determining that the simulator is abnormal in a case that no response is received from the simulator within a predetermined duration.

9. The method according to claim 5, wherein after the invoking, through the second invocation interface, a first invocation interface of the plurality of first invocation interfaces according to the second interface information, to cause the invoked first invocation interface to invoke a link library of the plurality of link libraries which corresponds to the first invocation interface according to the first interface information, the method further comprises:
terminating the invocation of the link library upon receiving a termination command, wherein the termination command is generated by the workstation.

10. An apparatus for controlling the universal system for link libraries according to claim 1, comprising:
a first obtaining unit, configured to obtain first interface information of a plurality of first invocation interfaces, wherein the plurality of first invocation interfaces correspond to the plurality of link libraries in a one-to-one manner, and are configured to invoke the corresponding link libraries;
a second obtaining unit, configured to obtain second interface information of a second invocation interface, wherein the second invocation interface is configured to invoke a first invocation interface of the plurality of first invocation interfaces; and
a first processing unit, configured to invoke, through the second invocation interface, a first invocation interface of the plurality of first invocation interfaces according to the second interface information, to cause the invoked first invocation interface to invoke a link library of the plurality of link libraries which corresponds to the first invocation interface according to the first interface information.

11. A method for controlling the universal system for link libraries according to claim 2, comprising:
obtaining first interface information of a plurality of first invocation interfaces, wherein the plurality of first invocation interfaces correspond to the plurality of link libraries in a one-to-one manner, and are configured to invoke the corresponding link libraries;
obtaining second interface information of a second invocation interface, wherein the second invocation interface is configured to invoke a first invocation interface of the plurality of first invocation interfaces; and
invoking, through the second invocation interface, a first invocation interface of the plurality of first invocation interfaces according to the second interface information, to cause the invoked first invocation interface to invoke a link library of the plurality of link libraries which corresponds to the first invocation interface according to the first interface information.

12. A method for controlling the universal system for link libraries according to claim 3, comprising:
obtaining first interface information of a plurality of first invocation interfaces, wherein the plurality of first invocation interfaces correspond to the plurality of link libraries in a one-to-one manner, and are configured to invoke the corresponding link libraries;
obtaining second interface information of a second invocation interface, wherein the second invocation interface is configured to invoke a first invocation interface of the plurality of first invocation interfaces; and
invoking, through the second invocation interface, a first invocation interface of the plurality of first invocation interfaces according to the second interface information, to cause the invoked first invocation interface to invoke a link library of the plurality of link libraries which corresponds to the first invocation interface according to the first interface information.

13. A method for controlling the universal system for link libraries according to claim 4, comprising:
obtaining first interface information of a plurality of first invocation interfaces, wherein the plurality of first invocation interfaces correspond to the plurality of link libraries in a one-to-one manner, and are configured to invoke the corresponding link libraries;
obtaining second interface information of a second invocation interface, wherein the second invocation interface is configured to invoke a first invocation interface of the plurality of first invocation interfaces; and
invoking, through the second invocation interface, a first invocation interface of the plurality of first invocation interfaces according to the second interface information, to cause the invoked first invocation interface to invoke a link library of the plurality of link libraries which corresponds to the first invocation interface according to the first interface information.
